(19) United States
(12) Patent Application Publication
(10) Pub. No.: US 2021/0054677 A1
(43) Pub. Date: Feb. 25, 2021

(54) CONSTRUCTION ELEMENT FOR LIGHT TRANSPARENT SOLUTIONS

(71) Applicant: COVESTRO DEUTSCHLAND AG, Leverkusen (DE)

(72) Inventors: Ruqi CHEN, Shanghai (CN); Heiko HOCKE, Leverkusen (DE); Dongbo ZHAO, Shanghai (CN); Yan DENG, Shanghai (CN); Min TANG, Shanghai (CN)

(73) Assignee: Covestro Deutschland AG, Leverkusen (DE)

(21) Appl. No.: 16/977,749

(22) PCT Filed: Mar. 5, 2018
(86) PCT No.: PCT/CN2018/077972

§ 371 Date: Sep. 2, 2020

(51) Int. Cl. E06B 3/04; E06B 3/56; E06B 7/23; C08G 18/78; C08G 18/32

(52) U.S. Cl. CPC E06B 3/04; E06B 3/56; C08G 18/3206; C08G 18/7893; E06B 7/2314

(57) ABSTRACT

A construction element A comprises a) at least one pane of glass B; and b) a frame C made of a non-coated thermoset polymeric composite material with a polymer matrix which is based on at least 50 wt.-% of an aliphatic polyisocyanate; and c) optionally at least one sealant D that connects the pane of glass B with frame C. It is characterized by an excellent long term weathering resistance, high durability and low maintenance efforts.

The present invention concerns a new construction element comprising at least a pane of glass, a frame made of polymeric composite materials based on aliphatic polyisocyanates and optionally a sealant. It is characterized by an excellent long term weathering resistance, high durability and low maintenance efforts.

Glass elements are an important part of many constructions, be it as glass facade in a modern skyscraper or a simple window of an ordinary family house. Other areas for the use of glass elements include the transportation industry (e.g. cars, trains, ships), agriculture (e.g. green houses, stables) or solar industry (solar modules). Besides the obvious property of separating two different environments and ensuring at the same time optical transparency and light guidance the glass elements are often also part of the temperature management of the construction and fulfill design and esthetical as well as mechanical support functions. For economic reasons these glass elements should have a long service life, often several decades of years. In most practical applications of glass elements at least one side of the glass construction element is exposed to the outside, i.e. to the weather conditions of the geographical region and the temperature changes over the year.

The pane of glass is usually embedded into a frame and often this construction glass element is later used as a combined unit in the installation. Materials of choice for the frame are alumina, polyvinyl chloride (PVC) and wood. Lately, windows with a frame comprising coated aromatic polyurethane composite material could be also found on the market.

Alumina is widely used as frame material especially for facades and solar modules. It combines very good mechanical properties with good weathering fastness. To achieve the outstanding chemical resistance the alumina is usually surface treated, e.g. by anode oxidation. Nevertheless, in salt water environment or mist alumina will gradually react with water. Furthermore, an expensive coating must be applied if colors other than the “typical” alumina silver color are desired. A further disadvantage is the high thermal conductivity of alumina in window applications or its electrical conductivity in solar modules. Furthermore, the coefficient of linear thermal expansion of alumina is significant higher than that of glass. This difference leads to challenges especially for the edge sealing in larger parts. Despite its good recyclability in principle, the costs for alumina are rather high, and the carbon footprint is high due to its energy consumption during the production.

PVC is used often for window frames. It has good weathering fastness, low thermal conductivity, requires low maintenance and is cheap. However, the mechanical properties (especially stiffness) are insufficient for bigger parts and a core of steel or composite material is required for support. Also, the coefficient of linear thermal expansion is about 6 times larger than that of glass. PVC recycling is also difficult and incineration or a fire may produce highly toxic dioxin and HCl gas.

Wood has good thermal isolating properties, is bio-based (renewable) and exhibits a high esthetical value, but is also expensive. It requires frequent maintenance by coating and the weathering fastness is low. Wood also needs to be protected against insects and fungal growth. Furthermore, the coefficient of linear thermal expansion is about 6 times bigger than that of glass. In addition, wood may change its size due to moisture content of the environment (swelling). The carbon footprint of wood is low which makes it a material of choice where sustainability is of high concern and costs are of less important.

Lately, polymeric composites have been proposed by BASF, Huntsman, Bayer MaterialScience and others for window frames, doors and solar modules. These composites have been often thermoplastic or thermoset based polymers as matrix materials and glass fibers as reinforcing fillers. Typical examples of matrix materials are polybutyleneterephthalate (PBT) and blends thereof as well as polyurethanes based on aromatic polyisocyanates. Although these composites provide many advantages such as good mechanical performance, low coefficient of linear thermal expansion, basically no electrical conductivity and very low thermal conductivity, however, as such they are not suitable for long term outdoor applications. In order to prevent degradation they need protective coatings. If the composites are manufactured by the pultrusion process, the application of coatings is even difficult due to the release agent on the surface of such parts. Thus, further treatment may be required to achieve a good bond between the polyurethane body and the coating. These additional processing steps make such solutions expensive and the overall long term durability of such coated composites has not yet been proven.

In general, pre-assembled constructions elements comprising coated parts need to be handled with care during their whole lifetime starting from their production, transportation, installation and work time since any chipping or other damage of the coating will impair their function or service life. Either costly repair or even replacement may be the consequence of careless handling.

As shown above, all current solutions for big glass construction elements on the market have their limitations in the application of long term outdoor usage either due to shortcomings regarding weather fastness, electrical or thermal conductivity, mechanical long term performance or thermal expansion coefficient, and no solution combines all necessary properties for such applications, e.g. for solar modules or windows in green houses. Hence, the problem underlying the present invention was the provision of a construction element which has all the favorable properties set forth above without the drawbacks of the conventional solutions.

Therefore, in a first embodiment the present invention relates to a construction element A comprising
a) at least one pane of glass B; and
b) a frame C made of a non-coated thermoset polymeric composite material with a polymer matrix which is based on at least 50 wt.-% of an aliphatic polyisocyanate; and
c) optionally at least one sealant D that connects the pane of glass B with frame C;
wherein (i) the difference of the coefficient of linear thermal expansion of the pane of glass B and of the frame C (measured in axial direction) is less than 600% at 20° C.; and (ii) at least 25% of the circumference of the pane of glass B is embedded into the frame C; and (iii) at least some areas of the construction element A including partly its glass B, its frame C and optionally its sealant D are exposed to the outdoor weather conditions.

Construction Element A

The construction element A according to the invention comprises at least one pane of glass B, one frame made of polymeric composite material C and optionally one sealant D that connects the pane of glass B with the frame C. The frame C stabilizes the pane B mechanically and optionally offers further elements to mount the construction element A. It may surround the pane of glass B completely or partly. However, it is essential that at least 25% of the circumference of the pane of glass B are embedded into the frame C.

In one preferred embodiment, the construction element A is a window comprising a window pane, a window frame surrounding at least 25% of the circumference of said window pane and optionally a sealant which connects the window pane and the window frame.

The construction element A is at least partially exposed to outdoor conditions. Preferably at least a part of the frame C is exposed to rain and/or solar radiation without any type of screen which protects the exposed part of the frame from said exposure.

In an embodiment of the invention the construction element A—when exposed to accelerated weathering test according to standard SAE J 2527—basically shows stable properties, such as appearance or mechanical performance, for at least 1000 h testing time, more preferably for at least 2000 h testing time, even more preferably for at least 5000 h testing time and most preferably for at least 10000 h. “Basically stable” means that the specific property will not deteriorate more than 20%, preferably not more than 15% and most preferably not more than 10%. Relevant properties are mechanical load tests and transparency of the glass. Electrical conductivity will not change by more than 2 orders magnitude (100 times), preferably not more than 1 order magnitude (10 times) and most preferably by not more than 0.5 orders magnitude (5 times). Thermal conductivity will not increase by more than 200%, preferably not more than 100% and most preferably by not more than 50%. Most preferably all properties remain at the same level as before.

In a preferred embodiment of the invention the construction element A is part of a solar module. As such exposed to accelerated weathering tests (thermal cycling test 10.11, humidity freeze test 10.12, damp heat test 10.13) as required by certification of solar modules (standard IEC 61215:2005) it will pass the tests at least once, preferably at least twice and more preferably at least 3 times without any significant visible changes or decrease of its performance. Moreover, a solar module based on construction element A will pass the certification required by standard IEC 61215:2005.

The construction element A when used in an application is at least exposed partly to outdoor conditions. Preferably the element A is exposed to outdoor conditions in sum at least 5 years, preferably at least 10 years, more preferably at least 15 years and most preferably at least 20 years.

Furthermore, at least 10% of the surface area of construction element A is exposed to outdoor conditions, preferably at least 20% of the surface area, more preferably at least 30% of the surface area and most preferably 50% of the surface area.

Most preferred are applications of the construction element A where at least 10% of the surface area of the element are exposed to outdoor conditions for at least 5 years in sum.

Pane of Glass B

The pane of glass B used in the construction element A may have different compositions depending on the final requirements of the applications. Typical examples are soda-lime-silica glass, i.e. normal window glass, fused quartz, solar glass, borosilicate and aluminosilicate glass. In addition, the glass may contain impurities such as oxides and other compounds of iron, cobalt, lead, zinc, copper, cerium, boron, thorium, barium, gold in order to modify mechanical properties, chemical and corrosion resistance, color, adsorption properties, refractive index and wavelength transmittance or reflection.

The pane of glass B might be formed by different production processes including blowing or pressing steps. Most preferred with respect to the invention is flat glass produced by float glass process. In this process, molten glass is floating on a bed of molten metal, typically tin, to give a sheet with uniform thickness and very flat surface.

The pane of glass B can also be coated on one or both sides. Coatings might be used to introduce or improve certain properties, for example optical properties such as reflection and wavelength cut off, easy-to-clean functions, surface polarity changes or simply mechanical properties such as e.g. scratch resistance.

The pane of glass B used in the construction element A has a thickness between 0.5 mm and 20 mm, preferably between 1.0 mm and 10 mm, more preferably between 1.5 mm and 7 mm and most preferably between 3.0 mm and 5.2 mm.

In another embodiment of the invention the surface area of the pane of glass is at least 0.5 m², preferably at least 1.0 m², more preferably at least 1.25 m² and most preferably at least 1.5 m². Preferably, the surface area is not larger than 10 m². The surface area is defined as the area that one side (the biggest) of the pane of glass exhibits, and that is not covered by the frame.

According to the invention the advantages of the new construction element A are especially emphasized if the pane of glass B of the element is large. Large in the meaning of the invention means that the circumference of the pane of pane B is at least 2.0 m, preferably more than 5.0 m, more preferably more than 10.0 m, and most preferably more than 20.0 m, while having the surface area defined in the paragraph above. Preferably, the circumference is not larger than 25.0 m for practical reasons.

Preferably, the glass of the panel B has a refractive index between 1.30 and 3.50, more preferably between 1.30 and 2.50, even more preferably between 1.40 and 2.00 and most preferably between 1.45 and 1.70. The refractive index is measured at a wavelength of 589 nm at 23° C.

The glass of pane B has a coefficient of linear thermal expansion between 2.5*10⁻⁶ K⁻¹ and 12*10⁻⁶ K⁻¹, preferably between 3.0*10⁻⁶ K⁻¹ and 11.0*10⁻⁶ K⁻¹, more preferably between 7.0*10⁻⁶ K⁻¹ and 10.0*10⁻⁶ K⁻¹ and most preferably between 8.0*10⁻⁶ K⁻¹ and 10.0*10⁻⁶ K⁻¹ at 20° C.

Preferably, the pane of glass B has an average light transmittance of at least 50%, more preferably at least 70%, even more preferably at least 80% and most preferably at least 90% of the visible light between 400 nm and 700 nm at 23° C.

Frame C

The frame C is shaped to surround at least a part of the circumference of the pane B. This means that the frame C covers at least a part of the edge of pane B and additionally a part of the surface adjacent to said edge so that pane B is moved into its intended position and kept in this position by orientating frame C.

A preferred shape for this purpose is a profile with a notch or an indention into which the edge of pane B can be inserted so that pane B is friction-locked with frame C or form-locked. Thus, the actual shape of the frame C is determined by the shape of the edges of the pane of glass B. If the optional sealant D is present, the required notch in the profile is large enough to insert the pane B as well as the required amount of sealant while meeting the requirements of friction-lock or form-lock.

Preferably, at least 25% of the circumference of pane B are surrounded by frame C. More preferably at least 50% and even more preferably at least 75% of the circumference of pane B are surrounded by frame C. Most preferably pane B is completely surrounded by frame C.

Frame C consists of a composite material comprising inorganic fibers embedded in a polymer matrix. Said composite material is, preferably, electrically and/or thermally insulating.

Electrical isolation can improve the durability of devices and may also contribute to a safe handling, particularly where high currency is involved. For example, solar modules suffer sometimes from an effect called PID (potential induced degradation). The suggested cause is the high voltage of up to 1500 V of serially connected modules that is due to the alumina frame in direct contact with the glass-polymer-stack which leads to a migration of ions, e.g. sodium ion, from the pane of glass into the silicon cell. An electrically non-conductive frame prevents such degradation and as a result improves the life time and efficiency of the solar module. The electrical resistivity of frame C is therefore preferably at least 10⁹ Ohm, more preferably at least 10¹² Ohm and even more preferably at least 10¹⁴ Ohm measured according to standard ASTM D257.

The term “coated” or “coating” means that there is an additional layer or covering of material applied on top of the surface of the substrate (core material, composite). This layer has a distinct thickness and a boundary that separates this layer from the substrate. In general, the chemical composition of this layer is different from the resin of the composite. The layer is applied to the composite surface after forming the composite part, and often even in a separate process step. The coating usually fulfills functional requirements such as protection, surface modification of mechanical or chemical nature, or simply decorative appearance. The term “non-coated” means that such layer does not exist on at least 20%, preferably at least 50% and more preferably at least 75% of the composite part. Most preferred is that no such layer, i.e. no coating, is applied to the composite part.

The inorganic fibers may be glass fibers or basalt fibers, however, glass fibers are preferred. Preferably, the composite material of frame C has a fiber content between 40 wt.-% and 95 wt.-%, more preferably between 50 wt.-% and 90 wt.-% and even more preferably between 60 wt.-% and 90 wt.-%. Most preferred is a glass fiber content of frame C between 70 wt.-% and 85 wt.-%. The content of glass fiber is given with respect to the overall weight of the composite material.

In order to facilitate better the embedding of the pane of glass B into the frame C the coefficient of linear thermal expansion (CLTE) as measured in axial direction should be preferably same or at least similar for glass B and frame C. Therefore variances of temperature which are typically encountered in outdoor conditions due to seasonal changes and the night-day-rhythm cause less stress on the connection of the pane with the frame or sealant. In addition, more freedom of design and higher accuracy of the parts and consequently better appearance of construction element A are advantageous side effects.

The CLTE of the frame C in axial direction, i.e. parallel to the fiber orientation, is between 2.5*10⁻⁶ K⁻¹ and 12*10⁻⁶ K⁻¹, preferably between 3.0*10⁻⁶ K⁻¹ and 11.0*10⁻⁶ K⁻¹, more preferably between 5.0*10⁻⁶ K⁻¹ and 10.0*10⁻⁶ K⁻¹ and most preferably between 7.0*10⁻⁶ K⁻¹ and 10.0*10⁻⁶ K⁻¹ at 20° C.

In another embodiment of the invention the difference of CLTE of the pane of glass B and of the frame C measured in axial direction, i.e. parallel to the fiber orientation, is not more than 200%, preferably not more than 100%, more preferably not more than 50% and most preferably not more than 25% at 20° C.

Composite Material

The meaning of the term “composite material” is well known to the person skilled in the art. It refers to a material made of inorganic fibers, particularly glass or basalt fibers, which are embedded into a polymer matrix. Preferably, the composite material is produced by the pultrusion process which is well known in the art.

Polymer Matrix

The matrix material of frame C might be a thermoset or thermoplastic material. Preferred is a thermoset material. Even more preferred is a thermoset material based on aliphatic polyisocyanates. Such thermoset materials based on aliphatic polyisocyanates contain at least 50 wt.-%, more preferably at least 70 wt.-% and even more preferably at least 80 wt.-% of aliphatic and cycloaliphatic polyisocyanates. Aliphatic and cycloaliphatic polyisocyanates useful for manufacturing the polymer matrix are monomeric polyisocyanates as well as oligomeric polyisocyanates. Furthermore, the reaction mixture used for manufacturing the polymer matrix does not contain more than 40 wt.-%, preferably not more than 20 wt.-%, more preferably not more than 10 wt.-%, even more preferably not more than 5 wt.-% and most preferably not more than 1 wt.-% aromatic and araliphatic polyisocyanates.

Aliphatic polyisocyanates which are suitable for the manufacture of the polymer matrix are 1,4-diisocyanatobutane (BDI), 1,5-diisocyanatopentane (PDI), 1,6-diisocyanatohexane (HDI), 2-methyl-1,5-diisocyanatopentane, 1,5-diisocyanato-2,2-dimethylpentane, 2,2,4- or 2,4,4-trimethyl-1,6-diisocyanatohexane, 1,10-diiisocyanatodecane, 1,3- and 1,4-diisocyanatocyclohexane, 1,4-diisocyanato-3,3,5-trimethylcyclohexane, 1,3-diisocyanato-2-methylcyclohexane, 1,3-diisocyanato-4-methylcyclohexane, 1-isocyanato-3,3,5-trimethyl-5-isocyanatomethylcyclohexane isophorone diisocyanate (IPDI), 1-isocyanato-1-methyl-4(3)-isocyanatomethylcyclohexane, 2,4′- and 4,4′-diisocyanatodicyclohexylmethane (H12M DI), 1,3- and 1,4-bis(isocyanatomethyl)cyclohexane, bis(isocyanatomethyl)norbornane, 4,4′-diisocyanato-3,3′-dimethyldicyclohexylmethane, 4,4′-diisocyanato-3,3′,5,5′-tetramethyldicyclohexylmethane, 4,4′-diisocyanato-1,1′-bi(cyclohexyl), 4,4′-diisocyanato-3,3′-dimethyl-1,1′-bi(cyclohexyl). Preferred is the use of HDI, PDI and IPDI. Particularly preferred is the use of HDI.

Said aliphatic may be used as such, i.e. as monomeric polyisocyanates, for manufacturing the polymeric composite material. However, they may be also used as oligomeric polyisocyanates obtained from the reaction of two monomeric polyisocyanates. This oligomerization leads to oligomeric polyisocyanates linked by at least one structure selected from the group consisting of uretdione, isocyanurate, allophanate, biuret, iminooxadiazinedione and/or oxadiazinetrione structures.

In order to achieve the desirable resistance of the material and its excellent mechanical properties, it is essential that the amount of ester and ether moieties in the polymer matrix is limited. Therefore, the ratio of aliphatic polyisocyanates and isocyanate reactive compounds other than the short chain polyols defined below in the reaction mixture is at least 5:1 (weight/weight), preferably at least 10:1 (weight/weight) and most preferably at least 20:1 (weight/weight). An “isocyanate reactive compound” as understood in the present application is any compound which carries at least one hydroxyl, thiol or amino group.

Short chain polyols which are suitable for manufacturing a polymer matrix according to the present invention have an average functionality of at least two and an OH content between 25% by weight and 60% by weight, preferably between 30% by weight and 60% by weight and more preferably between 35% by weight and 60% by weight.

Preferred short chain polyols are glycerol, 1,1,1-trimethylolpropane, 1,1,1-trimethylolethane, pentaerythritol, 1,2,10-decanetriol, 1,2,8-octanetriol and sugar alcohols. Particularly preferred is glycerol.

The polymer matrix is preferably manufactured from a reaction mixture comprising aliphatic isocyanates as defined above and short chain polyols as defined above, wherein the molar ratio between isocyanate groups and hydroxyl groups of the short chain polyols in the reaction mixture is at least 0.8:1.0, preferably 0.9:1.0, more preferably 1.1:1.0, even more preferably 1.3:1.0 and most preferably 1.5:1.0. There is no upper limit to this range because the formation of the polymer matrix is not dependent on the formation of urethane groups but can also be mediated by the formation of are isocyanurate groups, uretdione groups, biuret groups, iminooxadiazinedione and oxadiazintrione groups.

In a preferred embodiment of the present invention the molar ratio of isocyanate groups to all groups reactive with isocyanate groups in the reaction mixture used for manufacturing the polymer matrix is at least 2:1, preferably at least 5:1 and more preferably at least 10:1. Thus, the amount of any isocyanate reactive compound—including short chain polyols—is limited in this embodiment of the present invention.

Therefore, in this embodiment the polymer matrix is predominantly crosslinked by functional groups which are formed by the reaction of one isocyanate group with another isocyanate group. Such functional groups are isocyanurate groups, uretdione groups, biuret groups, iminooxadiazinedione and oxadiazintrione groups.

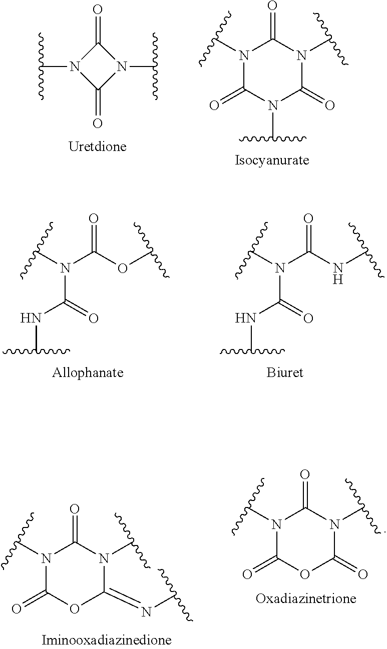 [SMILES: *N1C(=O)N(*)C1=O ; *n1c(=O)n(*)c(=O)n(*)c1=O ; *NC(=O)N(*)C(=O)O* ; *NC(=O)N(*)C(=O)N* ; */N=c1/oc(=O)n(*)c(=O)n1* ; *n1c(=O)oc(=O)n(*)c1=O]

The person skilled in the art knows many catalysts and the appropriate reaction conditions for crosslinking isocyanate groups.

A useful catalyst for manufacturing the composite material from a reaction mixture with a low content of isocyanate reactive groups comprises potassium acetate or potassium octoate and polyethylene glycol. Particularly useful are potassium acetate and a polyethylene glycol with a number-average molecular weight Mn between 350 and 400 g/mol. The polyethylene glycol preferably has a polydispersity of less than 5.

This catalyst has sufficient solubility or dispersibility in the reaction mixture in the amounts that are required for initiation of the crosslinking reaction. The trimerization catalyst is therefore preferably added to the polyisocyanate resin composition in neat form.

“Addition of the trimerization catalyst in neat form” means that the metal salt is dissolved or at least suspended in the polyether. The proportion of the metal salt in this solution is less than 50% by weight, preferably less than 25% by weight, more preferably less than 20% by weight or less than 15% by weight, and especially less than 10% by weight. However, the proportion is in any case greater than 0.01% by weight. The aforementioned proportions are based on the total weight of metal salt and polyether.

The crosslinking is preferably effected at temperatures between 80° C. and 350° C., more preferably between 100° C. and 300° C. and most preferably between 150° C. and 250° C.

If significant amounts of short chain polyols are present in the reaction mixture, any catalyst which mediates the formation of urethane groups can be used. Suitable catalysts can be found, for example, in Becker/Braun, Kunststoffhandbuch Band 7, Polyurethane [Plastics handbook, Volume 7, Polyurethanes], chapter 3.4. A particular catalyst that can be used is a compound selected from the group of the amines and organylmetal compounds, preferably from the group of the organyltin compounds and of the organylbismuth compounds, and particularly preferably dibutyltin dilaurate.

The quantity of catalyst added, based on sums of the masses of the polyisocyanate component and of the short chain polyol component, is from 0.001 to 0.100% by weight, preferably from 0.002 to 0.050% by weight and particularly preferably from 0.005 to 0.030% by weight.

Sealant D

In a preferred embodiment of the present invention the construction element A additionally comprises a sealant D which ensures a good connection between the frame C and the embedded glass pane B. Moreover, in case of using a sandwich element, e.g. a stack of one or multiple panes, or a pane pre-assembled with other (film) sheets the sealant D may also act as barrier to prevent moisture or air ingress.

Sealants have been developed for all kind of requirements and the variety is rather wide. Depending on the actual application the sealant D comprises a polymeric, elastic material that is based on polysilicon, polyesters, polyethers, polyurethans, polyacrylics, thermoplastic elastomers, thermoplastic olefins or rubber polymers. Suitable materials and their properties are well known in the art. Starting materials for sealants may include but are not limited to isocyanates, epoxies, acrylates, silicones, olefins, amines, alcohols and carboxylic acids and their derivatives. Often, besides radical scavengers and UV blockers additional fillers such as carbonates, silicates, sulfates, graphite or carbon blacks and other inorganic fillers are used in quite substantial amounts to lower the price, enhance the durability and improve or optimize the mechanical properties.

According to the invention all sealants can be used that exhibits a good weather fastness and provide the required mechanical performance for the sealing of glass B and frame C. The appropriate sealant can be easily selected and purchased from the recommendations given by the producers.

In a preferred embodiment of the invention the sealant is based on silicone or polyurethanes, preferred are silicones. These are easy to handle and commercially available from different companies, for example Du Pont, Dow Corning, Momentive, Lord, Henkel and Sika.

In another preferred embodiment, the present invention relates to the use of the construction element according to any of the previous claims in an application wherein said use is characterized by exposure of at least a part of the construction to outdoor conditions for more than 5 years in total.

In yet another preferred embodiment, the present invention relates to the use of the construction element according to any of the previous claims in an application wherein said use is characterized by exposure of at least a 10% of the surface area of the construction element to outdoor conditions for more than 5 years in total.

The following examples are only intended to illustrate the invention. They shall not limit the scope of the claims in any way.

### EXAMPLES

Desmodur® N 3600 is an HDI trimer (NCO functionality >3) with an NCO content of 23.0% by weight from Covestro AG. The viscosity is about 1200 mPas at 23° C. (DIN EN ISO 3219/A.3).

Glycerol (1,2,3-Propantriol) with a purity of 99.0% was sourced from Calbiochem bezogen.

Baydur® PUL 20PL05 is a mixture of polyols and auxiliaries from Covestro AG and is used for production of glass fibre-containing profiles composed of polyurethane in the pultrusion process. The viscosity is about 1600 mPas at 20° C. (DIN 53019).

Desmodur® PUL 10PL01 is a mixture of diphenylmethane 4,4′-diisocyanate (MDI) with isomers and higher-functionality homologs having an NCO content of about 31% by weight from Covestro AG and is used for production of glass fibre-containing profiles composed of polyurethane in the pultrusion process. The viscosity is 160-240 mPas at 25° C. (2011-0248603-94).

Dibutyltin dilaurate (DBTL) was sourced with a purity of >99% by weight from ACROS under the Tinstab® BL277 name.

Polyethylene glycol 400 was sourced with a purity of >99% by weight from ACROS.

Potassium acetate was sourced with a purity of >99% by weight from ACROS.

The INT-1940 ® separating agent was acquired from Axel Plastics Research Laboratories, INC. and, according to the datasheet, is a mixture of organic fatty acids and esters.

The zinc stearate were acquired from SysKem Chemie GmbH.

The glass fiber was glass fiber bundles with standard size for UP, VE and epoxy resins with the product name ‘Advantex 399’ with 4800 tex from 3B-fibreglass. According to the datasheet, the glass fibers have a diameter of 24 micrometres, are boron-free and consist of E-CR glass. The tensile modulus is 81-83 GPa, the tensile strength 2200-2400 MPa and the density 2.62 g/cm³.

The solar glass pane was purchased from Flat Glass Group, type low iron pattern glass, 3.2 mm thickness.

The solar backsheet was purchased from Jolywood, type TPT-3501.

The encapsulant material was EVA purchased from First Applied Materials, type F406.

The sealant was a silicone sealant from Tonsan, type Tonsan 1527.

Preparation of the Trimerization Catalyst

Potassium acetate (50.0 g) was stirred in the PEG 400 (950.0 g) at room temperature until all of it had dissolved. In this way, a 5% by weight solution of potassium acetate in PEG 400 was obtained and was used as catalyst without further treatment.

Preparation of the Resin Mixture

The isocyanate was initially charged in an open vessel at room temperature and stirred by means of a Dispermat® and dissolver disc at 100 revolutions per minute (rpm). Subsequently, first the separating agent and then the catalyst were added, the stirrer speed was increased to 300 rpm and the whole mixture was stirred for a further 10 min, so as to form a homogeneous mixture. This mixture was used without further treatment for the pultrusion.

### Production of Frame C

### Example 1

Aliphatic Polyurethane-Based Frame (Frame C for Inventive Example)

A profile for a frame was pultruded using Desmodur N 3600 (8.56 kg), glycerine (1.38 kg), release agent INT-1940 ® (0.30 kg), DBTL (0.008 kg) and glass fiber rovings (126 rovings). The rovings were pulled into an injection box in which the resin mixture was pumped, and impregnated. Afterwards, the wetted fibers were passed through a heated dye (temperature 200° C.). The pulling speed was 0.3 m/min. The resulting profile was used without further treatment.

The samples after performing the weathering test according to SAE J 2527 (10000 h) and the UV tests (A and B); 5000 h) did not show in any change on the surface quality (visual inspection) after 10000 hours. The glass fiber content of the profile was 80.8 wt.-% (DIN EN ISO 1172/A). The coefficient of linear thermal expansion in axial direction was 8.9e-6/K.

### Example 2

Aliphatic Polyisocyanurate-Based Frame (Frame C for Inventive Example)

A profile for a frame was pultruded using Desmodur N 3600 (9.45 kg), release agent INT-1940 ® (0.30 kg), trimerisation catalyst 100 (0.2 kg), zinc stearate (0.05 kg) and glass fiber rovings (126 rovings). The rovings were pulled into an injection box in which the resin mixture was pumped, and impregnated. Afterwards, the wetted fibers were passed through a heated dye (temperature 200° C.). The pulling speed was 0.3 m/min. The resulting profile was used without further treatment.

The samples after performing the weathering test according to SAE J 2527 (10000 h) and the UV tests (A and B); 5000 h) did not show any change on the surface quality or (visual inspection) after 10000 hours. The glass fiber content of the profile was 80.8 wt.-% (DIN EN ISO 1172/A). The coefficient of linear thermal expansion in axial direction was 8.9e-6/K.

Example for Construction Element A (Inventive Example 3)

A pane of glass (solar glass, 3.2 mm, 1.60 m×1.00 m) was rimmed using over the whole circumference the frame C of example 1 using a silicone sealant. The finished construction element A was put outdoors (Shanghai) for more than 12 months without any change of appearance.

Example for Construction Element A (Inventive Example 4)

A pane of glass (solar glass, 3.2 mm, 1.60 m×1.00 m) was rimmed using over the whole circumference the frame C of example 2, and using a silicone sealant. The finished construction element A was put outdoor (Shanghai) for more than 12 months without any change of appearance.

Example for Construction Element A Used in a Solar Module (Inventive Example 5)

A sandwich stack consisting of a pane of glass (solar glass, 3.2 mm, 1.60 m×1.00 m), EVA-sheet, wired solar cells, EVA-sheet and a backsheet was assembled by vacuum lamination process as well known in the industry. The whole circumference of the stack was enclosed by the frame C of example 2 and using a silicone sealant. The finished solar module assembly was subjected to the tests according to standard IEC 61215:2005 and passed these.

Aromatic PU Frame (Non-Inventive Example for Frame)

A profile for a frame was pultruded using Baydur® PUL 20PL05, Desmodur® PUL 10PL01 and release agent 4 wt.-% and glass fiber rovings (126 rovings). The rovings were pulled into an injection box in which the resin mixture was pumped, and impregnated. Afterwards, the wetted fibers were passed through a heated dye (temperature 160° C.). The pulling speed was 0.6 m/min. The resulting profile was used without further treatment.

The samples after performing the weathering test showed strong surface changes such as pristine glass fibers on the surface and discoloration. The test according to SAE J 2527 was already stopped after 1000 h due to sample degradation. The profile could not be used for making a construction element A.

1.-10. (canceled)

11. Construction element A comprising
a) at least one pane of glass B; and
b) a frame C made of a non-coated thermoset polymeric composite material with a polymer matrix which is based on at least 50 wt.-% of an aliphatic polyisocyanate; and
c) optionally at least one sealant D that connects the pane of glass B with frame C;
wherein (i) the difference of the coefficient of linear thermal expansion of the pane of glass B and of the frame C (measured in axial direction) is less than 600% at 20° C.; and (ii) at least 25% of the circumference of the pane of glass B is embedded into the frame C; and (iii) at least some areas of the construction element A including partly its glass B, its frame C and optionally its sealant D are exposed to the outdoor weather conditions.

12. The construction element of claim 11, wherein the pane of glass B has a circumference between 2.0 m and 25.0 m.

13. The construction element of claim 11, wherein at least 20% of frame C are non-coated.

14. The construction element of claim 11, wherein the thermoset polymeric composite material is manufactured from a reaction mixture having a mass ratio of aliphatic polyisocyanates and isocyanate reactive compounds other than the short chain polyols of more than 5:1.

15. The construction element of claim 11, wherein the aliphatic polyisocyanate comprises at least one aliphatic polyisocyanate selected from the group consisting of 1,6-diisocyanatohexane, 1,5-diisocyanatopentane and isophorone diisocyanate.

16. The construction element of claim 11, wherein the thermoset polymeric composite material is manufactured from a reaction mixture comprising short chain polyols.

17. The construction element of claim 16, wherein the reaction mixture contains at least one short chain polyol selected from the group consisting of glycerol, 1,1,1-trimethylolpropane, 1,1,1-trimethylolethane, pentaerythritol, 1,2,10-decanetriol, 1,2,8-octanetriol and sugar alcohols.

18. The construction element of claim 11, wherein the thermoset polymeric composite material is manufactured from a reaction mixture having a molar ratio of isocyanate groups to all groups reactive with isocyanate groups of at least 2:1.

19. The use of the construction element according to claim 11 in an application wherein said use is characterized by exposure of at least a part of the construction to outdoor conditions for more than 5 years in total.

20. The use of the construction element according to claim 11 in an application wherein said use is characterized by exposure of at least a 10% of the surface area of the construction element to outdoor conditions for more than 5 years in total.
